(19) United States
(12) Patent Application Publication
(10) Pub. No.: US 2026/0234004 A1
(43) Pub. Date: Aug. 13, 2026

(54) METHOD FOR MANUFACTURING THIN FILM USING SURFACE-FUNCTIONALIZED GRAPHENE LAYER AND THIN FILM MANUFACTURED USING SAME

(71) Applicant: SEOUL NATIONAL UNIVERSITY R&DB FOUNDATION, Seoul (KR)

(72) Inventors: Gwan Hyoung LEE, Seoul (KR); Hui Je RYU, Seoul (KR)

(73) Assignee: SEOUL NATIONAL UNIVERSITY R&DB FOUNDATION, Seoul (KR)

(21) Appl. No.: 18/705,191

(22) PCT Filed: Oct. 19, 2022
(86) PCT No.: PCT/KR2022/015921

§ 371 Date: Apr. 10, 2026

(30) Foreign Application Priority Data
Oct. 27, 2021 (KR) 10- 2021-0144189

(51) Int. Cl. C01B 32/194

(52) U.S. Cl. CPC C01B 32/194; C01B 2204/04; C01B 2204/22

(57) ABSTRACT

The present invention relates to a method for manufacturing a thin film, using a surface-functionalized graphene layer, and a thin film manufactured using same and, specifically, to a method for manufacturing a thin film using a surface-functionalized graphene layer and a thin film manufactured using same, wherein the graphene layer is disposed on a substrate and allows the production and attachment/detachment of a uniform thin film irrespective of materials of the substrate.

### TECHNICAL FIELD

This application claims priority from and the benefit of Korean Patent Application No. 10-2021-0144189, filed on Oct. 27, 2021, which is hereby incorporated by reference for all purposes as if set forth herein.

The present disclosure relates to a method of manufacturing a thin film using a graphene layer having a surface functionalized and a thin film manufactured by using the same, and particularly, to a method Of manufacturing a thin film using a graphene layer having a surface functionalized, which enables a uniform thin film to be manufactured and detached regardless of the material of a substrate because a graphene layer is disposed on the substrate, and a thin film manufactured by using the same.

### BACKGROUND ART

In the existing thin film growth technology, a thin film is directly grown on a lower substrate, and a chemical vapor deposition (CVD) method or an atomic layer deposition (ALD) method is used in addition to a physical vapor deposition (PVD) method, such as sputter and thermal evaporation. Such a conventional thin film growth technology achieves the thin-filming of a bulk material through the vaporization of a target material using various energy sources and the selection of various precursors, but the uniformity and crystallinity of the thin film that is formed due to chemical/physical interactions between a precursor for forming the thin film and a lower substrate are determined. That is, there is a problem in that the selection of a material of the thin film, which may be deposited, is limited due to differences between the crystallographic, thermal, mechanical, and electrical characteristics of the lower substrate and the deposited material.

Furthermore, a conventional two-dimensional nano material surface processing method for the activation of thin film deposition includes a method of forming an organic material on graphene, a surface processing method through UV/ozone processing, a surface processing method through hydrogen/oxygen plasma processing, etc. Surface energy of graphene is increased through the medium of a physical combination of the organic material and the forming of a defect in the two-dimensional nano material by a high energy source. Unlike in control of a surface combination of graphene, the physical combination and the defect have a limit in being used as a deposition growth substrate having an atomic layer thickness, which is proposed by the present disclosure, because the physical combination and the defect are accompanied by the degradation of interface quality.

Accordingly, there is an urgent need to develop a technology for attaching, to a lower substrate, graphene having a functional group combined with a surface thereof controlled in order to deposit a thin film that is not related to the type and characteristic of the lower substrate and performing a process of depositing the thin film, and a technology capable of increasing a degree of freedom of surface characteristic modification by modifying a surface of graphene having a several-atomic layer thickness on a lower substrate without directly modifying a surface of the lower substrate and overcoming a limit in selecting the type of thin film by excluding an interaction between a precursor for forming a thin film and a lower substrate.

### DISCLOSURE

### Technical Problem

An object of the present disclosure is to provide a method of manufacturing a thin film using a graphene layer having a surface functionalized, which can manufacture thin films having various materials even without being influenced by the material of substrate by functionalizing a surface of a graphene layer that is deposited on the substrate in order to prevent the characteristics of a thin film from being degraded due to differences between the crystallographic, thermal, mechanical, and electrical characteristics of the substrate and a material to be deposited in a process of manufacturing the thin film, and a thin film manufactured by using the same.

However, objects to be solved by present disclosure are not limited to the aforementioned objects, and the other objects not described above may be evidently understood from the following description by those skilled in the art.

### Technical Solution

An embodiment of the present disclosure provides a method of manufacturing a thin film using a graphene layer having a surface functionalized, including providing a graphene layer on one surface of a substrate, functionalizing a surface of the graphene layer by treating, with a reaction material, the other surface that is a surface opposite one surface of the graphene layer in which the substrate is provided, manufacturing a composite by depositing a thin film on the other surface of the functionalized graphene layer, and separating the thin film from the composite by heating the composite.

According to an embodiment of the present disclosure, the graphene layer having one to five layers may be provided.

According to an embodiment of the present disclosure, the reaction material may be one selected from a group consisting of XeF₂, CF₄, SF₆, HF, H₂, CH₄, and a combination of them.

According to an embodiment of the present disclosure, if the reaction material is one selected from a group consisting of XeF₂, CF₄, SF₆, HF, H₂, CH₄, and a combination of them, the reaction material may be heated or may have a plasma form in the functionalizing of the surface of the graphene layer.

According to an embodiment of the present disclosure, the substrate and the graphene layer may be combined by a van der Waals force or chemically combined.

According to an embodiment of the present disclosure, the thin film may have a dipole force in a direction parallel to a direction in which the thin film is deposited on the graphene layer.

According to an embodiment of the present disclosure, a method of heating the composite may be furnace heating, heating by ultraviolet radiation, or heating by laser radiation.

According to an embodiment of the present disclosure, the separating of the thin film may include providing a support film or an additional thin film on a surface opposite a surface Of the functionalized graphene layer on which the composite is deposited, and separating the thin film and the support film or the additional thin film by heating the composite provided with the support film or the additional thin film.

An embodiment of the present disclosure provides a thin film manufactured by the manufacturing method.

### Advantageous Effects

The method of manufacturing a thin film using a graphene layer having a surface functionalized according to an embodiment of the present disclosure can manufacture various thin films without being limited to the material of a substrate and can minimize the occurrence of a defect in a surface of a thin film or the generation of an alien substance by separating the thin film through heating.

Specifically, a thin film formed on an upper side is formed as a substrate on which the thin film is grown by depositing a functionalized graphene layer on the substrate that is disposed on a lower side. Accordingly, a thin film having a heterogeneous junction structure in which various materials attributable to differences between the crystallographic characteristics, thermal characteristics, mechanical characteristics, and electrical characteristics of the substrate and the thin film have been combined may be manufactured. In general, a thin film is not uniformly deposited on graphene because the nucleation of a material deposited on the graphene is difficult because a defect, such as a dangling bond, is less in the graphene. However, a uniform thin film may be formed on graphene to which a functional group has been attached because the graphene has many nucleation sites and a fast spreading speed on a surface of the graphene. Furthermore, if a material having a dipole is deposited within a material, such as ferroelectric material, a ferroelectric characteristic of a thin film can be improved because the functionalized graphene layer may have a dipole moment in a vertical direction.

The thin film according to an embodiment of the present disclosure can maintain its unique characteristic although a thickness thereof is reduced, and can be independently controlled without a support layer. Accordingly, a thin film having a structure bonded by a heterogeneous material which cannot be formed by a deposition method can be formed by stacking another thin film that has been formed in graphene.

Specifically, a conventional method of forming defect in a surface of graphene, as a technology for directly growing a thin film on the graphene, the grown thin film cannot be separated because the thin film is chemically combined with the defect of the graphene. Furthermore, if a thin film of an organic material is directly grown on graphene having the thin film formed on a surface thereof, it is difficult to separate the thin film, and there is a problem in that an interface is contaminated when a stack process is performed on a surface of a separated thin film due to contamination attributable to the organic material. However, a graphene layer and a thin film formed on a functionalized graphene layer can be easily physically separated because a functional group of the graphene layer is detached from the thin film through heating by decomposing a functional group combination of the graphene layer. A high-quality thin film that is manufactured or fabricated through a method of stacking a thin film having a heterogeneous junction structure with which a material which cannot be formed through a deposition method has been combined can be transferred to a flexible substrate because the separated thin film may be stacked on an external substrate or another thin film.

Effects of the present disclosure are not limited to the aforementioned effects, and effects not described above may be evidently understood from the specification and the accompanying drawings by those skilled in the art.

### BRIEF DESCRIPTION OF DRAWINGS

FIG. 1 is a flowchart of a method of manufacturing a thin film using a graphene layer having a surface functionalized according to an embodiment of the present disclosure.

FIG. 2 is schematic diagram schematically illustrating a method of manufacturing a thin film using a graphene layer having a surface functionalized according to an embodiment of the present disclosure.

FIG. 3 is a photo of a form in which heat was applied to a composite, which was photographed by using an optical microscope, in Embodiment 1 according to an embodiment of the present disclosure.

FIG. 4 is a photo of a form in which an Al₂O₃ thin film manufactured by Embodiment 1 according to an embodiment of the present disclosure was transferred to a SiO₂/Si substrate, which was photographed by using an optical microscope.

FIG. 5 is a photo that was photographed by using an atomic force microscope after the Al₂O₃ thin film manufactured by Embodiment 1 according to an embodiment of the present disclosure was transferred to the SiO₂/Si substrate, and is a graph illustrating the heights of a substrate and a thin film.

FIG. 6 is a photo of a surface of the Al₂O₃ thin film manufactured by Embodiment 1 according to an embodiment of. the present disclosure, which was enlarged and photographed by using an atomic force microscope, and is a graph illustrating the height of the surface.

FIG. 7 is a photo of a field effect transistor in which a channel was formed by using a ZnO thin film manufactured by Embodiment 2 according to an embodiment of the present disclosure, which was photographed by using an optical microscope.

FIG. 8 is a graph illustrating a V_{GS}-I_{DS} transfer characteristic of the field effect transistor in which the channel was formed by using the ZnO thin film, which was manufactured by Embodiment 2 according to an embodiment of the present disclosure.

### BEST MODE

Throughout this specification, when it is said that one component “includes” the other component, the word “include” will be understood to imply the inclusion of stated components but not the exclusion of any other components, unless explicitly described to the contrary.

In the entire specification of the present disclosure, when it is described that one member is placed “on” the other member, this includes a case in which one member adjoins the other member and a case where a third member is interposed between the two members.

In the entire specification of the present disclosure, “A and/or B” means “A and B, or A or B”.

Hereinafter, embodiments of the present disclosure will be described in detail.

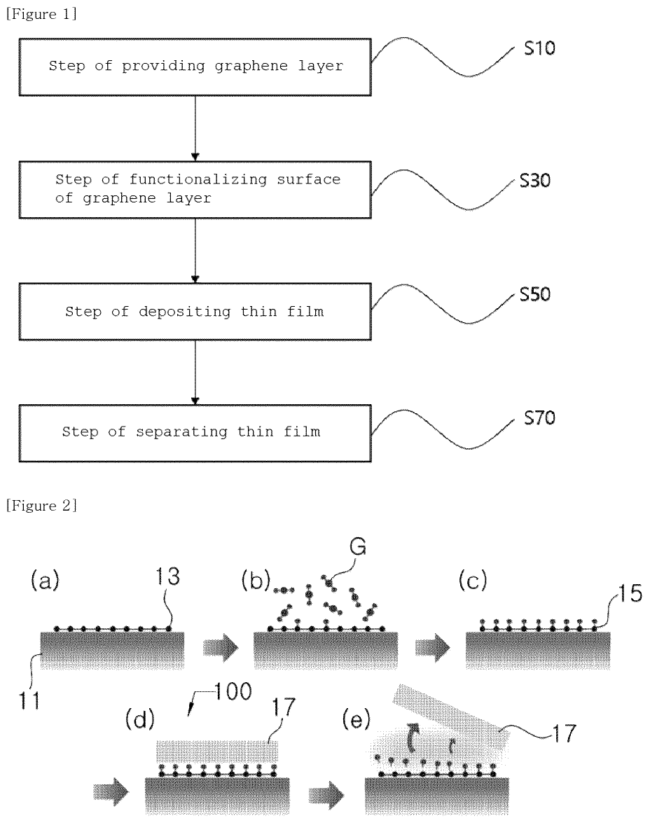

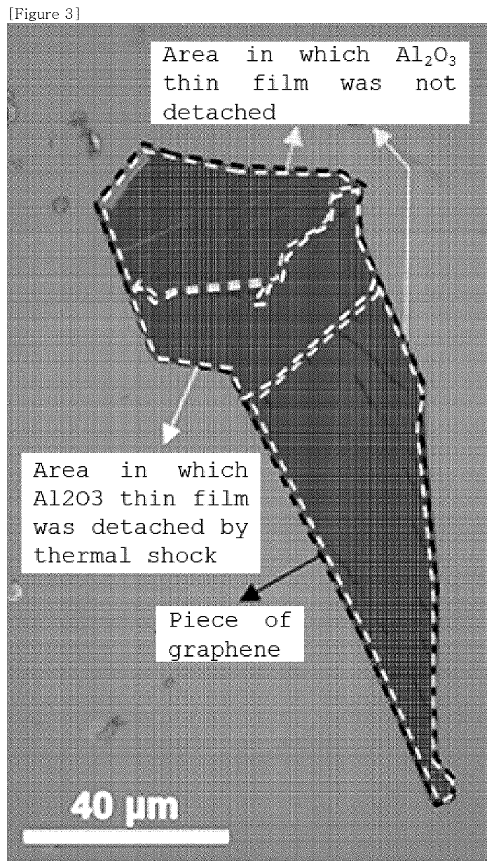

FIG. 1 is a flowchart of a method of manufacturing a thin film using graphene layer having a surface functionalized according to an embodiment of the present disclosure. FIG. 2 is a schematic diagram schematically illustrating a method of manufacturing a thin film using a graphene layer having a surface functionalized according to an embodiment of the present disclosure.

An embodiment of the present disclosure provides a method of manufacturing a thin film using a graphene layer having a surface functionalized, including a step of providing a graphene layer on one surface of a substrate; a step of functionalizing a surface of the graphene layer by treating, with a reaction material, the other surface that is a surface opposite one surface of the graphene layer in which the substrate is provided; a step of manufacturing a composite by depositing a thin film on the other surface of the functionalized graphene layer; and a step of separating the thin film from the composite by heating the composite.

The method of manufacturing a thin film using a graphene layer having a surface functionalized according to an embodiment of the present disclosure can manufacture various thin films without being limited to the material of a substrate and can minimize the occurrence of a defect in a surface of a thin film or the generation of an alien substance by separating the thin film through heating.

The method of manufacturing a thin film using graphene layer having a surface functionalized is described in detail with reference to FIGS. 1 and 2.

According to an embodiment of the present disclosure, step S10 of including a graphene layer 13 on one surface of the substrate 11 is included. As the graphene layer is included on one surface of the substrate as described above, thin films having various materials may be manufactured because the graphene layer is prevented from being influenced by a crystallographic characteristic, a thermal characteristic, a mechanical characteristic, and an electrical characteristic according to the material of the substrate. Specifically, the graphene layer, that is, a two-dimensional material, is a material that has been combined by a van der Waals (vdW) force without a chemical combination between an atomic layer and an atomic layer. The graphene layer may be stably present even at a very thin thickness (one-atomic layer to several-atomic layer thickness) because there is no chemical combination between the atomic layer and the atomic layer. Accordingly, the graphene layer has a mechanical characteristic, an electrical characteristic, an optical characteristic, and a chemical characteristic different from those of the existing bulky material. Furthermore, transparency and flexibility can be secured without the degradation of an electrical characteristic and a mechanical characteristic attributable to a thin thickness of the graphene layer, that is, a two-dimensional material.

According to an embodiment of the present disclosure, the substrate may be SiO₂/Si, glass, polycarbonate, polystyrene, or polyimide, but may be used without limitation if the substrate can physically support the graphene layer.

According to an embodiment of the present disclosure, the graphene layer 13 may be deposited on the substrate 11 by a physical vapor deposition (PVD) method, a chemical vapor deposition (CVD) method, an atomic layer deposition (ALD) method, and a physical peeling method (a method of physically peeling off the graphene layer from the graphene material). The graphene layer may be provided in a way to attach the graphene layer to the substrate after the graphene layer is manufactured. The graphene layer may be properly formed on the substrate according to circumstances because the graphene layer is provided by the aforementioned method.

According to an embodiment of the present disclosure, step S30 of functionalizing a surface of the graphene layer by treating the other surface, that is, a surface opposite the one surface of the graphene layer 13 in which the substrate 11 is provided, with a reaction material G included. As step S30 of functionalizing the surface of the graphene layer by treating the other surface, that is, the surface opposite the one surface of the graphene layer 13 in which the substrate 11 is provided, with the reaction material G is included as described above, the graphene layer may be functionalized, that is, fluorized or hydrogenated. A thin film precursor can be easily separated as will be described later by applying a thermal shock by heating the graphene layer having the surface functionalized. Specifically, a two-dimensional nano material, that is, a nano material having the widest surface area, is to control the type of combination of a surface, among methods of controlling the physical property. For example, functionalized graphene based on an sp³ combination may be manufactured by combining atoms, such as fluorine or hydrogen, with a surface of the graphene layer in which carbon forms the sp² combination. Accordingly, hydrophilicity/hydrophobicity in addition to an electrical characteristic and an optical characteristic may be adjusted by adjusting surface energy. Furthermore, uniform oxide having an atomic layer thickness may be formed through the functionalization of a layer unit.

According to an embodiment of the present disclosure, the functionalization of the surface of the graphene layer may include the hydrogenation, fluorization, or oxidation of the surface of the graphene layer or attaching molecules to the surface of the graphene layer. The physical property of the surface of the graphene layer to be implemented may be adjusted by selecting the functionalization of the surface of the graphene layer, from those described above.

According to an embodiment of the present disclosure, the time taken to treat the reaction material is not specially limited, but may be adjusted depending on the number of atomic layers that are functionalized.

According to an embodiment of the present disclosure, pressure for treating the reaction material is not specially limited, but may be adjusted depending on the number of atomic layers that are functionalized.

According to an embodiment of the present disclosure, the substrate may be heated in the step of being functionalized. Efficiency in which the graphene layer is functionalized can be improved because the substrate is heated in the functionalization step as described above.

According to an embodiment of the present disclosure, step S50 of manufacturing a composite 100 by depositing a thin film 17 on the other surface of a functionalized graphene layer 15 is included. As step S50 of manufacturing the composite 100 by depositing the thin film 17 on the other surface of the functionalized graphene layer 15 is included as described above, the graphene layer is composed of a surface sp³ combination unlike the graphene layer that forms the sp² combination. Accordingly, a high-quality thin film can be grown on surface of the functionalized graphene layer 15 because uniform nucleation can be induced when the thin film is grown due to high surface energy.

According to an embodiment of the present disclosure, a method of depositing the thin film 17 may be any one of a PVD method, a CVD method, or an ALD method. Deposition efficiency can be improved and a stable thin film can also be formed depending on a material by depositing the thin film 17 by the aforementioned method.

According to an embodiment of the present disclosure, step S70 of separating the thin film 17 from the composite 100 by heating the composite 100 is included. As step S70 of separating the thin film 17 from the composite 100 by heating the composite 100 is included as described above, a functional group of the surface of the functionalized graphene layer may be removed by heating, and the thin film deposited on the surface having the functional group is physically separated from the graphene layer in this process. Accordingly, the thin film having a nm thickness may be independently controlled without a support layer by detaching the thin film from the graphene layer, that is, separating the thin film from the graphene layer. The separated thin film may be manufactured to have a junction structure having heterogeneous materials, which cannot be formed through a deposition method, because the thin film may be stacked on an external substrate or another thin film.

According to an embodiment of the present disclosure, the thin film may be a ferroelectric material, metal, a semiconductor, an insulating film, etc. A material may be selected as the thin film without limitation depending on a characteristic to be implemented in the thin film.

According to an embodiment of the present disclosure, a temperature, pressure, and time for separating the thin film 17 from the composite 100 may be adjusted based on a combination between the thin film 17 and the functionalized graphene layer 15. The thin film 17 can be easily separated from the composite 100 and damage to the thin film can be prevented by adjusting the temperature, pressure, and time for separating the thin film 17 from the composite 100 as described above.

According to an embodiment of the present disclosure, the graphene layer 13 may have one to five layers. Thin films having various materials may be manufactured by preventing the graphene layer from being influenced by a crystallographic characteristic, a thermal characteristic, a mechanical characteristic, and an electrical characteristic according to the material of the substrate by adjusting the thickness of the graphene layer through the adjustment of the number of stacked layers of the graphene layer in the aforementioned range. Transparency and flexibility can be secured without the degradation of an electrical characteristic and a mechanical characteristic attributable to a thin thickness of the graphene layer, that is, a two-dimensional material.

According to an embodiment of the present disclosure, the thickness of the graphene layer 13 may be 0.34 nm to 3.4 nm. Thin films having various materials may be manufactured by preventing the graphene layer from being influenced by a crystallographic characteristic, a thermal characteristic, a mechanical characteristic, and an electrical characteristic according to the material of the substrate by adjusting the thickness of the graphene layer in the aforementioned range. Transparency and flexibility can be secured without the degradation Of an electrical characteristic and a mechanical characteristic attributable to a thin thickness of the graphene layer, that is, a two-dimensional material.

According to an embodiment of the present disclosure, the reaction material G may be one selected from a group consisting of XeF₂, CF₄, SF₆, HF, H₂, CH₄, and a combination of them. As the reaction material is selected as described above, the graphene layer may be functionalized, and the thin film may be easily separated through a thermal shock through heating. Furthermore, the reaction material having a gas state can prevent the substrate from being influenced by the reaction material because the reaction material cannot penetrate the graphene layer.

According to an embodiment of the present disclosure, the reaction material may be a gas, liquid, or plasma. Specifically, if the reaction material is XeF₂, the surface of the graphene layer may be treated with a gas. If the reaction material is HF, the surface of the graphene layer may be treated with liquid. If the reaction material is CF₄ or SF₆, the surface of the graphene layer may be treated with plasma. Furthermore, if a specific compound is used to adjust the functionalization characteristic of the surface of the graphene layer, the surface of the graphene layer may be treated based on a phase of the compound. The functionalization characteristic of the surface of the graphene layer can be easily adjusted by implementing the reaction material by a gas, liquid, or plasma as described above.

According to an embodiment of the present disclosure, if the reaction material is one selected from the group consisting of XeF₂, CF₄, SF₆, HF, H₂, CH₄, and a combination of them, the reaction material may be heated or may have a plasma form in the step of functionalizing the surface of the graphene layer. A property to be implemented by functionalizing the surface of the graphene layer may be adjusted by selecting the reaction material from those described above.

According to an embodiment of the present disclosure, the substrate 11 and the graphene layer 13 may be combined by the van der Waals force or chemically combined. As the substrate 11 and the graphene layer 13 are combined by the van der Waals force or chemically combined as described above, characteristics different from the mechanical characteristic, electrical characteristic, optical characteristic, and chemical characteristic of the substrate may be implemented, and junctions having various structures may be implemented.

According to an embodiment of the present disclosure, the thin film 17 may have a dipole force in a direction parallel to a direction in which the thin film 17 is deposited on the graphene layer 15. Specifically, functional group having the polarity of molecules is combined with the surface of the functionalized graphene layer. The thin film has the dipole force due to a difference between the polarity of the functional group and the polarity of the graphene layer. The dipole force of the functionalized graphene layer causes the dipole force in the thin film precursor stacked on the functionalized graphene layer. Accordingly, the thin film 17 may have the dipole force in the direction parallel to the direction in which the thin film 17 is deposited. Accordingly, the dielectric characteristic of the thin film can be increased.

According to an embodiment of the present disclosure, prior to step S30 of functionalizing the surface of the graphene layer, step S20 of performing purging by using an inactive gas may be further included. As step S20 of performing purging by using the inactive gas is further included prior to the functionalization step S30 as described above, the generation of an alien substance in the process of treating the graphene layer with the reaction material can be minimized.

According to an embodiment of the present disclosure, the inactive gas may be one selected from N₂, He, Ne, Ar, and a combination of them. The generation of an alien substance in the process of treating the graphene layer with the reaction material can be minimized by selecting the inactive gas from those described above.

According to an embodiment of the present disclosure, a heating temperature in step S70 of separating the thin film may be 300° C. or more. Specifically, the heating temperature may be 300° C. or more to 900° C. or less, 400° C. or more to 800° C. or less, 500° C. or more to 700° C. or less, 310° C. or more to 400° C. or less, 320° C. or more to 400° C. or less, 330° C. or more to 400° C. or less, 340° C. or more to 400° C. or less, 350° C. or more to 400° C. or less, 360° C. or more to 400° C. or less, or 370° C. or more to 400° C. or less. The thin film 17 may be easily peeled off from the functionalized graphene layer 15 by adjusting the heating temperature in step S70 of separating the thin film in the aforementioned range. Furthermore, the heating temperature may be adjusted to a temperature of 300° C. or less because the temperature is adjusted based on a functionalized functional group of the graphene layer.

According to an embodiment of the present disclosure, a method of heating the composite may include furnace heating, heating by ultraviolet radiation, or heating by laser radiation. The heating temperature in the step of separating the thin film can be easily adjusted and damage attributable to heat of the thin film can be prevented, by selecting the method of heating the composite from those described above.

According to an embodiment of the present disclosure, step S70 of separating the thin film 17 may include step S71 of providing a support film (not illustrated) or an additional thin film (not illustrated) on a surface opposite the surface that has been deposited on the functionalized graphene layer 15 of the composite 100; and step S73 of separating the thin film 17 and the support film (not illustrated) or the additional thin film (not illustrated) by heating the composite 100 in which the support film (not illustrated) or the additional thin film (not illustrated) has been provided. Specifically, after the support film or the additional thin film is attached on the thin film, the thin film may be manufactured by separating the thin film to which the support film has been attached by heating the composite. The usability of the thin film can be improved by manufacturing the thin film by separating the thin film to which the support film has been attached as described above.

According to an embodiment of the present disclosure, the additional thin film may be a thin film manufactured according to an embodiment of the present disclosure or may be another thin film, and may have the same material as the thin film that is used in the manufacturing process or may have a material different from that of the thin film that is used in the manufacturing process.

According to an embodiment of the present disclosure, the support film may be a polycarbonate film, and may be used without limitation if the support film has a bonding force between the support film and the thin film, which is greater than a bonding force between the functionalized graphene layer and the thin film.

An embodiment of the present disclosure provides the thin film 17 manufactured by the manufacturing method.

The thin film according to an embodiment of the present disclosure can maintain its unique characteristic although the thickness thereof is reduced, and can be independently controlled without a support layer. Accordingly, a thin film having a structure bonded by a heterogeneous material, which cannot be formed by a deposition method can be formed by stacking another thin film formed in each graphene.

### Mode for Invention

Hereinafter, embodiments of the present disclosure are described in detail in order to specifically describe the present disclosure, However, embodiments according to the present disclosure may be modified in other various forms, and the scope of the present disclosure is not construed as being limited to the following embodiments. Embodiments of this specification are provided to a person having ordinary knowledge in the art to more fully describe the present disclosure.

### Embodiment 1

The graphene layer having a 3 nm thickness was formed on the substrate, that is, SiO₂/Si, by using a physical peeling method. A surface of the graphene layer was fluorized by exposing graphene to a gas XeF₂ with 400 torr pressure at room temperature for 120 seconds. Thereafter, a composite was formed by depositing an Al₂O₃ thin film on the fluorized graphene layer through an atomic layer deposition method using trimethylaluminum (TMA) Al(CH₃)₃) and H₂O as a precursor. Thereafter, the thin film was separated in a way to apply a thermal shock by heating the composite at a temperature of 350° C. The separated thin film was moved and transferred to another SiO₂/Si substrate by using polycarbonate support film.

### Embodiment 2

The graphene layer having a 3 nm thickness was formed on the substrate, that is, SiO₂/Si, by using a physical peeling method. A surface of the graphene layer was fluorized by exposing graphene to a gas XeF₂ with 400 torr pressure at room temperature for 120 seconds. Thereafter, a composite was formed by depositing a ZnO thin film the fluorized graphene layer through an atomic layer deposition method using diethylzinc (DEZ) and H₂O as a precursor. Thereafter, the thin film was separated in a way to apply a thermal shock by heating the composite at a temperature of 350° C. The separated thin film was moved and transferred to another SiO₂/Si substrate by using a polycarbonate support film.

FIG. 3 is a photo of a form in which heat was applied to the composite, which was photographed by using an optical microscope, in an embodiment according to an embodiment of the present disclosure. Referring to FIG. 3, it was found that the Al₂O₃ thin film was separated from the fluorized graphene layer by a thermal shock applied to the composite.

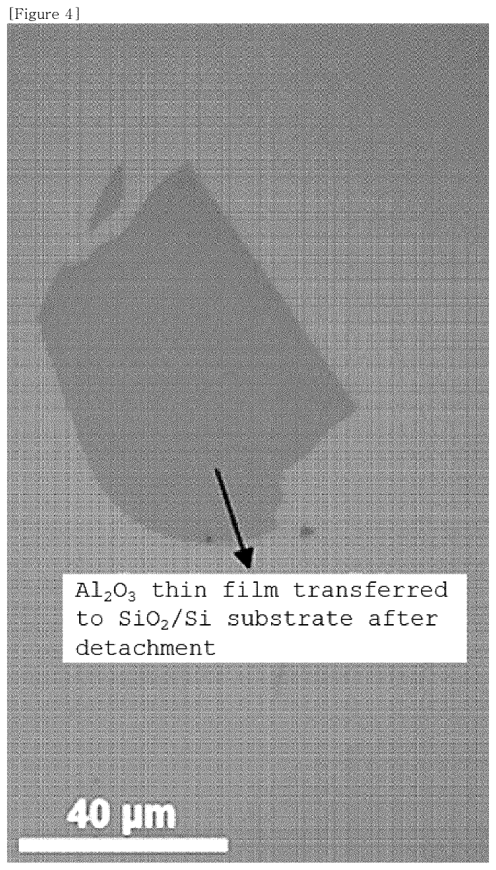

FIG. 4 is a photo of a form in which the Al₂O₃ thin film manufactured by an embodiment according to an embodiment of the present disclosure was transferred to the SiO₂/Si substrate, which was photographed by using an optical microscope. Referring to FIG. 4, it was found that the Al₂O₃ thin film could be easily transferred to another substrate by transferring the Al₂O₃ thin film manufactured in the embodiment to the SiO₂/Si substrate.

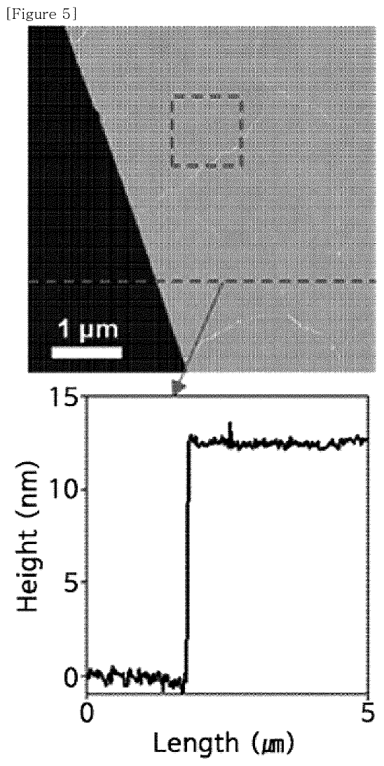

FIG. 5 is a photo that was photographed by using an atomic force microscope after the Al₂O₃ thin film manufactured by an embodiment according to an embodiment of the present disclosure was transferred to the SiO₂/Si substrate, and is a graph illustrating the heights of the substrate and the thin film. Referring to FIG. 5, it was found that various thin films, including the Al₂O₃ thin film having a thickness of about 12 nm, could be manufactured regardless of the material of the substrate and the thickness could be thinly formed.

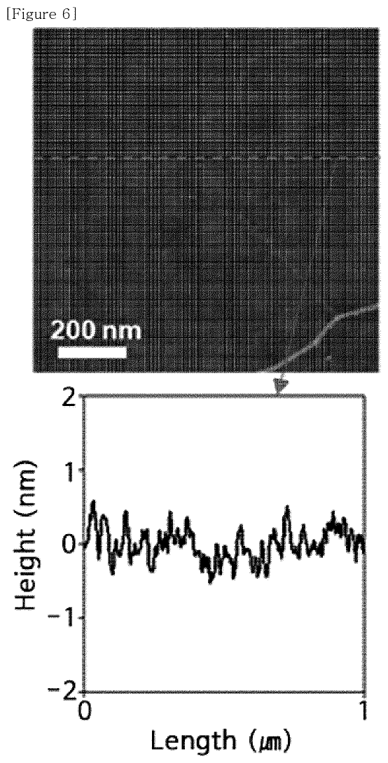

FIG. 6 is a photo of a surface of the Al₂O₃ thin film manufactured by an embodiment according to an embodiment of the present disclosure, which was enlarged and photographed by using an atomic force microscope, and is a graph illustrating the height of the surface. Referring to FIG. 6, it was found that roughness of the Al₂O₃ thin film was less than 1 nm.

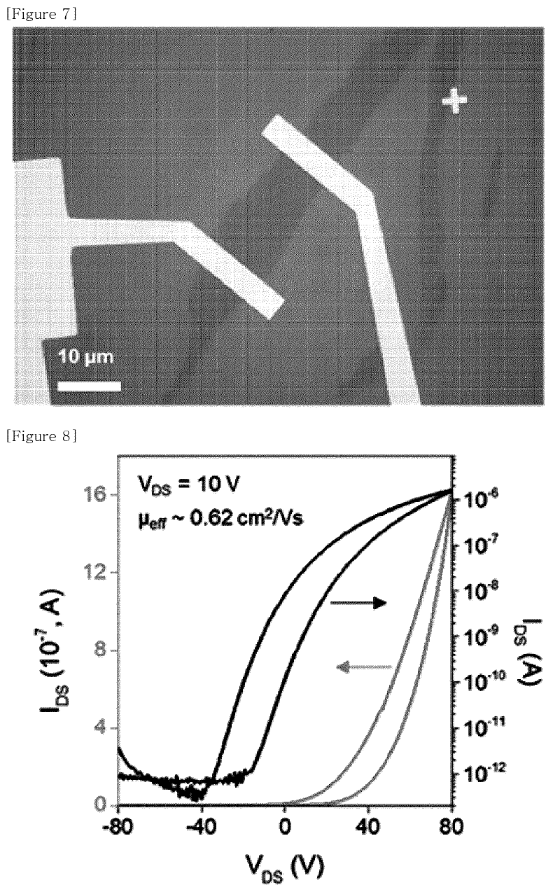

FIG. 7 is a photo of a field effect transistor in which a channel was formed by using the ZnO thin film manufactured by an embodiment according to an embodiment of the present disclosure, which was photographed by using an optical microscope. Referring to FIG. 7, it was found that the field effect transistor could be implemented although the channel was formed by using the ZnO thin film.

FIG. 8 is a graph illustrating a V_{GS}-I_{DS} transfer characteristic of the field effect transistor in which the channel was formed by using the ZnO thin film, which was manufactured by an embodiment according to an embodiment of the present disclosure. Specifically, FIG. 8 is the results in which the ZnO thin film formed on the fluorized graphene layer was detached by a thermal shock and moved to another SiO₂/Si substrate, then the field effect transistor was manufactured by using them, and a transfer characteristic thereof was measured. Referring to FIG. 8, ZnO is metal oxide which may be used as an N type semiconductor. As an oxygen concentration is reduced, an electrical characteristic of ZnO is changed from a semiconductor to metal. Considering that when the V_{GS} changes from −80 to 80 V, the I_{DS} has an on/off characteristic, ZnO operates as an N type semiconductor. This showed that the quality of the thin film on an FG was not degraded in a process of the thin film being subjected to the thermal shock.

As a result, in the method of manufacturing a thin film using a graphene layer having a surface functionalized and the thin film manufactured by using the same according to an embodiment of the present disclosure, thin films having various materials may be manufactured even without being influenced by the material of a substrate by fluorizing and hydriding a surface of the graphene layer that is deposited on the substrate in order to prevent the characteristics of the thin film from being degraded due to differences between crystallographic, thermal, mechanical, and electrical characteristics of the substrate and a material to be deposited in a process of manufacturing the thin film.

Although disclosure has been described above in connection with the limited embodiments, the present disclosure is not limited to the embodiments. A person having ordinary knowledge in the art to which the present disclosure pertains may modify and change the present disclosure within the technical spirit of the present disclosure and the equivalent range of the following claims.

### DESCRIPTION OF REFERENCE NUMERALS

S10: step of providing graphene layer
S30: step of functionalizing surface Of graphene layer
S50: step of depositing thin film
S70: step of separating thin film
11: substrate
13: graphene layer
15: functionalized graphene layer
17: thin film
100: composite
G: reaction material

1. A method of manufacturing a thin film using a graphene layer having a surface functionalized, the method comprising:
providing a graphene layer on one surface of a substrate;
functionalizing a surface of the graphene layer by treating, with a reaction material, the other surface that is a surface opposite one surface of the graphene layer in which the substrate is provided;
manufacturing a composite by depositing a thin film on the other surface of the functionalized graphene layer; and
separating the thin film from the composite by heating the composite.

2. The method of claim 1, wherein the graphene layer having one to five layers is provided.

3. The method of claim 1, wherein the reaction material is one selected from a group consisting of XeF₂, CF₄, SF₆, HF, H₂, CH₄, and a combination of them.

4. The method of claim 3, wherein if the reaction material is one selected from a group consisting of XeF₂, CF₄, SF₆, HF, H₂, CH₄, and a combination of them, the reaction material is heated or has a plasma form in the functionalizing of the surface of the graphene layer.

5. The method of claim 1, wherein the substrate and the graphene layer are combined by a van der Waals force or chemically combined.

6. The method of claim 1, wherein the thin film has a dipole force in a direction parallel to a direction in which the thin film is deposited on the graphene layer.

7. The method of claim 1, wherein a method of heating the composite is furnace heating, heating by ultraviolet radiation, or heating by laser radiation.

8. The method of claim 1, wherein the separating of the thin film comprises:
providing a support film or an additional thin film on a surface opposite a surface of the functionalized graphene layer on which the composite is deposited; and
separating the thin film and the support film or the additional thin film by heating the composite provided with the support film or the additional thin film.

9. A thin film manufactured according to the manufacturing method of claim 1.

10. A thin film manufactured according to the manufacturing method of claim 2.

11. A thin film manufactured according to the manufacturing method of claim 3.

12. A thin film manufactured according to the manufacturing method of claim 4.

13. A thin film manufactured according to the manufacturing method of claim 5.

14. A thin film manufactured according to the manufacturing method of claim 6.

15. A thin film manufactured according to the manufacturing method of claim 7.

16. A thin film manufactured according to the manufacturing method of claim 8.
